(19) United States
(12) Patent Application Publication
(10) Pub. No.: US 2006/0186494 A1
(43) Pub. Date: Aug. 24, 2006

(54) Semiconductor relay

(76) Inventors: Walter Apfelbacher, Freihung (DE); Annernarie Lehmeier, Ursensollen (DE); Johann Seitz, Amberg (DE)

Correspondence Address: HARNESS, DICKEY & PIERCE, P.L.C., P.O.BOX 8910, RESTON, VA, 20195, US

(21) Appl. No.: 10/551,048

(22) PCT Filed: Feb. 9, 2004
(86) PCT No.: PCT/EP04/01175

§ 371 Date: Sep. 27, 2005

(30) Foreign Application Priority Data
Mar. 28, 2003 (EP) 03007172.4

(51) Int. Cl. H01L 29/84

(52) U.S. Cl. 257/415

(57) ABSTRACT

A semiconductor relay includes an essentially parallelepiped-shaped housing that has a fastening side and four lateral surfaces, which are perpendicular thereto, and has a front side, which is opposite the fastening side. These lateral surfaces and front side serve as connecting sides. At least one electrical connecting element and at least one mechanical connecting element for connecting a functional module, which can be connected to the housing, are provided on a number of connecting sides.

The invention relates to a semiconductor relay having an essentially cuboid housing. A semiconductor relay is known, for example, from DE 199 56 445 C2.

A semiconductor relay or semiconductor contactor has connections for a main circuit or load circuit and for a control circuit. If additional functions, for example a monitoring or measurement function, are intended to be provided, then these are normally implemented with the aid of an additional appliance which is connected to the appropriate circuit or to the appropriate circuits. In this case, different appliances may be provided in particular for different monitoring functions, with the load circuit requirements being independent of the use of these appliances. The plurality of the appliances which can optionally be used involves considerable additional effort for configuration, storage, installation and commissioning in comparison to the use of exclusively one semiconductor relay or semiconductor contactor. Furthermore, the space requirement for the appliances to be installed in addition to the relay or contactor in a switchgear cabinet is significant.

The invention is based on the object of providing additional functions in circuits having a semiconductor relay or semiconductor contactor with particularly little installation effort, and with a particularly small amount of space being required.

According to the invention, this object is achieved by a semiconductor relay having the features of claim 1. The expression semiconductor relay in this case also covers appliances which are normally referred to as semiconductor contactors. The semiconductor relay has an essentially cuboid housing which can be attached to a holding apparatus, in particular a mounting rail, or to a heat sink, for example, by a face which is referred to as an attachment face. The other five faces of the housing are referred to jointly as connecting faces. Electrical connections are provided on one or more of these faces. A functional module which can be fitted to the housing can be connected to at least one of the connecting faces. A single functional module preferably makes contact with the housing on a plurality of faces, in particular on a side surface which is arranged at right angles to the attachment face and on a front face which is opposite the attachment face. In this case, by way of example, it is possible to provide for one face of the housing to be only mechanically connected to one face of the functional module, while a further face of the housing is connected both mechanically and electrically to a further face of the functional module. The functional module is connected to the control circuit and/or to the load circuit of the semiconductor relay.

The connection of the functional module to the housing of the semiconductor relay can preferably be produced and detached without the use of any tools, in particular by means of a snap-action connection. Alternatively or additionally, however, it is also possible to provide a screw connection, by way of example. A plurality of functional modules can preferably be coupled to a single housing of a semiconductor relay. The connection can likewise be provided between a plurality of functional modules.

The functional module which can be fitted to the relay housing is preferably no broader—with respect to the extent of a mounting rail—than the housing itself, so that the arrangement comprising the semiconductor relay and functional module requires virtually no additional space in a switchgear cabinet. The functional module is also distinguished by the capability to be retrofitted in existing switchgear installations in a very simple manner.

The mechanical and the electrical connection of the functional module to the semiconductor relay may be made successively or at the same time. The production of the electrical connection between the functional module and the semiconductor relay to the connection of the respective housing minimizes the wiring complexity, and at the same time provides protection against wiring errors. In this case corresponding contact-making elements, for example spring contacts, are provided in the housing of the semiconductor relay and in the functional module, and allow contact to be made with the drive electronics for the semiconductor relay, so that the functional module can directly influence the drive in the semiconductor relay. The electrical characteristics of the semiconductor relay to which the functional module has been added are preferably identical to the characteristics of a branch without any additional functions. This independence of the electrical characteristics of the main circuit or load circuit from the presence and the characteristics of the functional module means rational configuration as well as considerable savings for storage. Overall, the semiconductor relay and the functional modules which are compatible with it provide a product range which can be extended in a universal modular form, with the semiconductor relay also being operable without any restrictions with no functional module connected to it.

In order to make particularly good use of the space which is available for installation of the functional module in a switchgear cabinet and which is adjacent to the semiconductor relay, one preferred refinement of the functional module has not only a part which is adjacent to the front face of the semiconductor relay but also a part which is adjacent to one side surface, specifically a side surface which is aligned parallel to the mounting rail. The last-mentioned part in this case has a so-called base face, which is at least approximately aligned with the attachment face of the semiconductor relay. This base face is preferably opposite a plug connector strip on the front face of the functional module.

If the housing of the semiconductor relay has an opening which is also intended to remain accessible when the functional module is fitted, then, according to one preferred embodiment, two attachment limbs are integrally formed on the functional module on both sides of the opening, and are preferably provided in order to produce a snap-action connection between the functional module and the housing of the semiconductor relay. The attachment limbs are in this case aligned parallel to two side surfaces of the housing, provided that the opening is located on the front face of the housing, with the snap-action connection elements of the attachment limbs having the capability to be latched to the housing of the semiconductor relay, on an edge between the front face and one side surface of the housing.

The functional module may, for example, cover one or more functions: monitoring of the load circuit, power control in the load circuit, current measurement, analogue/digital signal conversion. The functional module may be drivable by means of analogue and/or digital signals. The advantage of the invention is, in particular, that prefabricated functional modules, and/or functional modules which can be retrofitted and can be snapped onto a semiconductor relay or a semiconductor contactor allow the functionality of the relay to be extended in a modular, simple form, and/or allow additional functions to be provided, preferably in the control circuit.

A plurality of exemplary embodiments of the invention will be explained in more detail in the following text with reference to a drawing, in which:

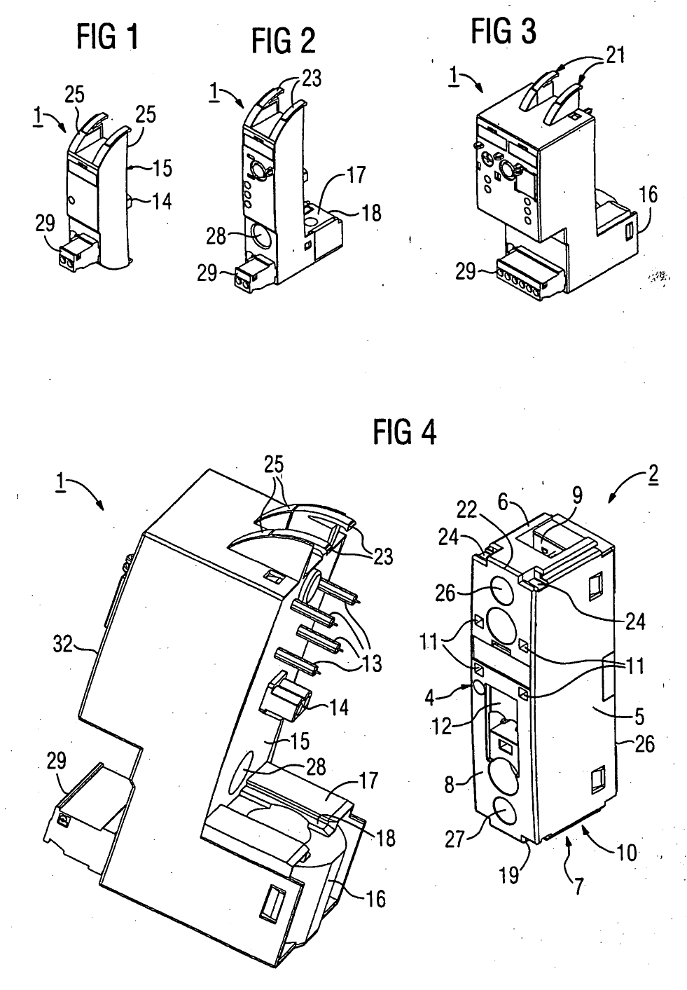

FIGS. 1 to 3 each show one exemplary embodiment of a functional module for a semiconductor relay,

FIG. 4 shows a semiconductor relay and a functional module which can be connected to it,

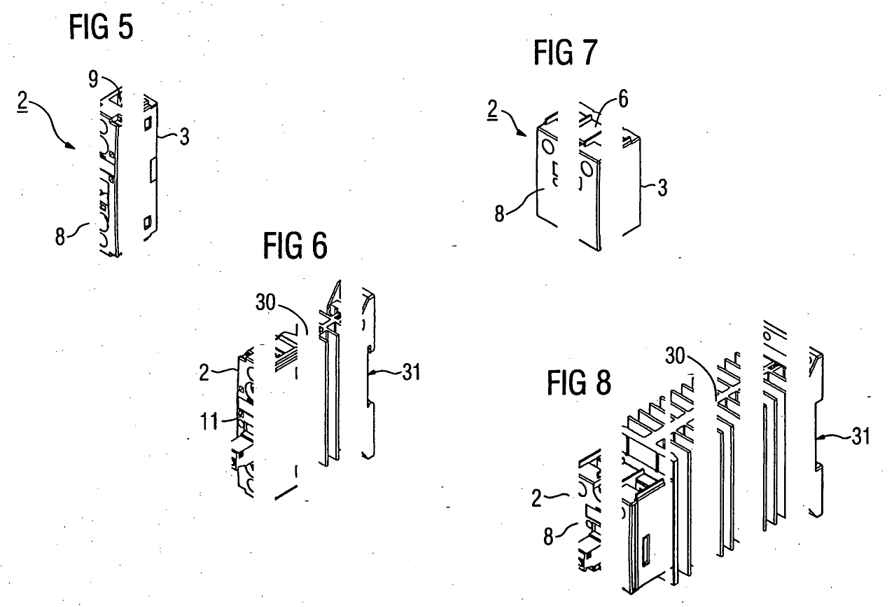

FIGS. 5 to 8 each show one exemplary embodiment of a semiconductor relay,

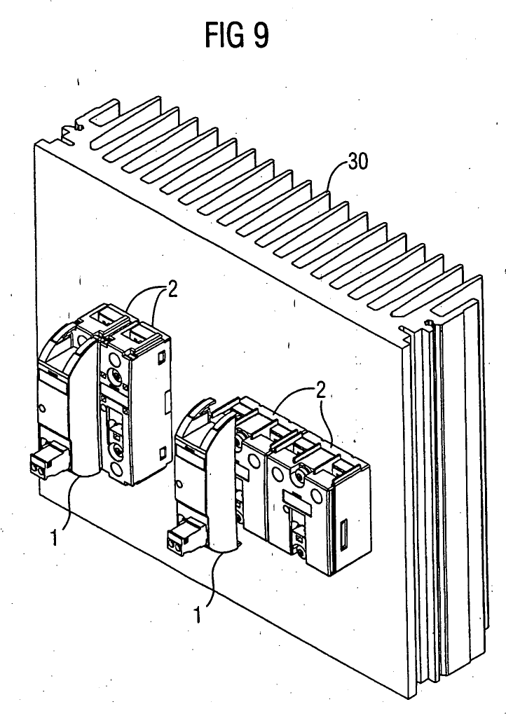

FIG. 9 shows a plurality of semiconductor relays and functional modules which interact with them, and

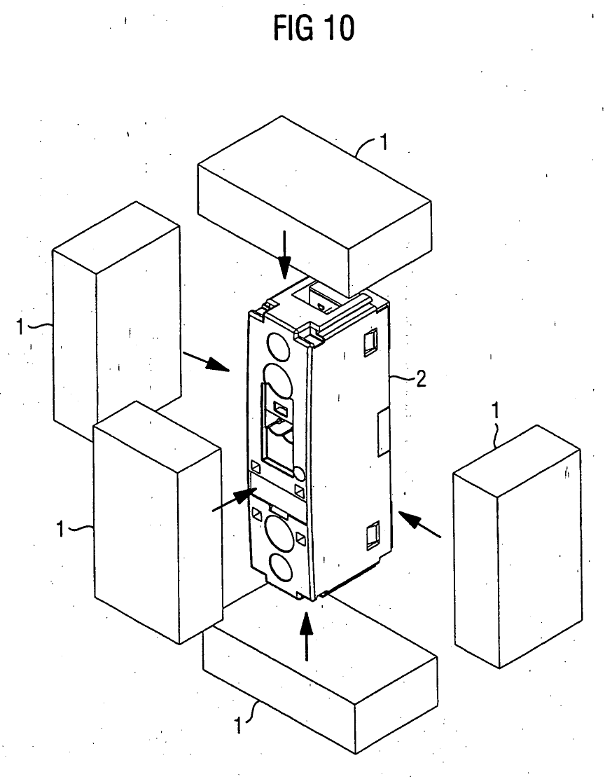

FIG. 10 shows a semiconductor relay and a plurality of schematically illustrated functional modules.

Mutually corresponding parts are provided with the same reference symbols in all of the Figures.

FIGS. 1 to 3 each show one embodiment of a functional module 1 for a semiconductor relay or a semiconductor contactor. The functional module 1 acts at least on the control circuit of the semiconductor relay and replaces conventional appliances which have to be physically connected to the semiconductor relay in order to drive it. FIG. 4 shows the functional module 1, which is also illustrated in FIG. 3, together with an associated semiconductor relay 2. The semiconductor relay 2 has an attachment face 3 which is intended for attachment to a load-bearing structure, two longitudinal faces 4, 5 and two lateral faces 6, 7, referred to collectively as side surfaces 4, 5, 6, 7, as well as a front face 8 which is opposite the attachment face 3. The longitudinal and lateral faces 4, 5, 6, 7 and the front face 8 are also referred to in the same way as connecting faces, with no connections being provided on the longitudinal faces 4, 5 in the illustrated exemplary embodiment. The housing, which is produced from a plastic, of the semiconductor relay 2 has an essentially cuboid shape and is annotated with the reference symbol 20. Main connections 9, 10 which are associated with the main circuit or load circuit are accessible from the lateral faces 6, 7 of the housing 20, while a plurality of connecting sockets 11, 12 are accessible from the front face 8. Pins 13 or a plug 14 of the functional module 1 engage or engages as electrical connection elements in the connecting sockets 11, 12. The pins 13 make contact with contact surfaces, which cannot be seen, in the semiconductor relay 2 and form spring contacts. All of the electrical connection elements between the semiconductor relay 2 and the functional module 1 are thus located on the front face 8 and on a contact-making face 15 (which corresponds to this) of the functional module 1, or are accessible from the respective face 8, 15. There is no need for any additional wiring between the functional module 1 and the semiconductor relay 2. The semiconductor relay 2 can be combined with different functional modules 1, depending on the requirements. If the functional module 1, which is provided for example for current regulation in the load circuit, is intended to be connected to the semiconductor relay 2 both on the control current side and on the load current side, these connection are produced automatically by the functional module 1 being snapped onto the semiconductor relay 2. The risk of incorrect contact being made is thus fundamentally precluded.

The functional modules 1 illustrated in FIGS. 2 to 4 are essentially L-shaped, with the first, longer L limb resting on the front face 8 of the semiconductor relay 2, and the second, shorter L-limb resting on the lateral face 7. The last-mentioned L-limb is bounded by a base face 16, which is arranged as a straight-line extension of the attachment face 3 of the semiconductor relay 2. A fixing face 17 of the functional module 1 runs at right angles to the base face 16, adjacent to the lateral face 7, and has a groove 18 which interacts with a rail 19 (which is used as a corresponding mechanical connection element) on the lateral face 7 of the housing 20 of the semiconductor relay 2. The functional module 1, whose housing 32 is produced from plastic in the same way as the housing 20 of the semiconductor relay 2, can thus be pushed onto it. A snap-action connection 21 is provided on the opposite lateral face 6 and fixes the functional module 1 on an edge 22 of the housing 20. The snap-action connection 21 is formed from two snap-action hooks 23, which latch in depressions 24, which form further mechanical connection elements, on the lateral face 6. The snap-action hooks 23 are integrally formed in a sprung manner on in each case one attachment limb 25 on the functional module 1, which is aligned parallel to the longitudinal faces 4, 5. A free space remains between the attachment limbs 25 in order to ensure accessibility to an opening 26, which is associated with the main connection 9, in the housing 20 even after the functional module 1 has been snapped onto it. A further opening 27, which is associated with the main connection 10, in the housing 20 is accessible through an operating opening 28 in the housing 32 of the functional module 1. A plug connecting strip 29 is located on the front face of the functional module 1, opposite the base face 16.

FIGS. 5 to 8 each show a semiconductor relay 2, with the embodiment illustrated in FIG. 5 corresponding to the type illustrated in FIG. 4. FIGS. 6 and 8 each show a semiconductor contactor 2, which is likewise covered by the expression semiconductor relay and is attached to a heat sink 30. On the rear face, that is to say opposite the semiconductor relay 2, the heat sink has a cutout 31 by means of which the relay 2 can be attached to a mounting rail, which is not illustrated but runs at right angles to the longitudinal faces 4, 5.

In the exemplary embodiment shown in FIG. 9, a plurality of semiconductor relays 2 are attached to a common heat sink 30. By way of example, two functional modules 1 are furthermore illustrated in the form shown in FIG. 1, one of which is snapped onto a semiconductor relay 2. No tools are required for snapping the functional module 1 onto the semiconductor relay 2, or for removing it, either.

The exemplary embodiment illustrated in FIG. 10 shows a semiconductor relay 2 as well as five purely symbolically illustrated functional modules 1, which can be attached to all of the connecting faces 4, 5, 6, 7, 8 of the housing 20. In addition to the electrical and mechanical connection between the semiconductor relay 2 and the functional modules 1, such connections may also be provided in a manner which is not illustrated in any more detail between the individual functional modules 1.

1. A semiconductor relay, comprising:
an essentially cuboid housing including an attachment face and including, as connecting faces, four side surfaces arranged at right angles to the attachment face and a front face opposite the attachment face; and at least one electrical connection element and at least one mechanical connection element, provided on a number of the connecting faces, for connection of a functional module connectable to the housing.

2. The semiconductor relay as claimed in claim 1, wherein the functional module is connected to two connecting faces.

3. The semiconductor relay as claimed in claim 1, wherein the functional module is provided for load circuit monitoring.

4. The semiconductor relay as claimed in claim 1, wherein the functional module is provided for power control in the load circuit.

5. The semiconductor relay as claimed in claim 1, wherein the functional module is drivable by use of an analogue signal.

6. The semiconductor relay as claimed in claim 1, wherein the functional module is provided for current measurement.

7. The semiconductor relay as claimed in claim 1, wherein the functional module is provided for analogue/digital signal conversion.

8. The semiconductor relay as claimed in claim 1, wherein the functional module is connectable to the housing without the use of any tools.

9. The semiconductor relay as claimed in claim 8, wherein the functional module is snapable onto the housing.

10. The semiconductor relay as claimed in claim 1, wherein a plurality of functional modules are connectable to the housing.

11. The semiconductor relay as claimed in claim 1, wherein the functional module includes a base face aligned with the attachment face of the housing.

12. The semiconductor relay as claimed in claim 1, wherein the functional module has two attachment limbs, arranged on both sides of an opening in the housing and each aligned parallel to one side surface.

13. The semiconductor relay as claimed in claim 2, wherein the functional module is provided for load circuit monitoring.

14. The semiconductor relay as claimed in claim 2, wherein the functional module is provided for power control in the load circuit.
